(19) United States
(12) Patent Application Publication
(10) Pub. No.: US 2010/0133638 A1
(43) Pub. Date: Jun. 3, 2010

(54) Image sensors and methods of manufacturing the same

(75) Inventors: Jong Eun Park, Seongnam-si (KR); Jung Chak Ahn, Yongin-si (KR); Yong Jei Lee, Seongnam-si (KR); Dong-Yoon Jang, Hwasung-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/591,724

(22) Filed: Nov. 30, 2009

(30) Foreign Application Priority Data
Dec. 1, 2008 (KR) 10-2008-0120532
Dec. 1, 2008 (KR) 10-2008-0120534

(51) Int. Cl. H01L 31/0224; H01L 21/768

(52) U.S. Cl. 257/443; 438/80; 257/E31.124; 257/E21.575

(57) ABSTRACT

An image sensor includes a plurality of photodiodes, a plurality of wells isolating the plurality of photodiodes from each other, and a plurality of conductive layers or conductive lines for suppressing a dark current generated at the surface of the photodiodes and in the wells in response to a bias voltage.

### CROSS-REFERENCE TO RELATED APPLICATION(S)

This application claims priority under 35 U.S.C. §119 to Korean Patent Application Nos. 10-2008-0120534 filed on Dec. 1, 2008, and 10-2008-0120532 filed on Dec. 1, 2008, in the Korean Intellectual Property Office, the entire contents of which are incorporated herein by reference.

### BACKGROUND

1. Field

Example embodiments of inventive concepts relate to image sensors, for example, image sensors capable of suppressing dark currents at a silicon surface above a photodiode and/or in a well region. Example embodiments of inventive concepts also relate to methods of manufacturing image sensors.

2. Description of the Conventional Art

Image sensors are usually classified as charge-coupled device (CCD) image sensors and complementary metal-oxide semiconductor (CMOS) image sensors (CISs). Image sensors include a plurality of pixels arranged in a two-dimensional matrix. Each pixel outputs an image signal in response to incident light energy. In more detail, each pixel accumulates photo-generated charges corresponding to the quantity of light input through a photodiode and outputs a pixel signal based on the accumulated charge.

In a conventional image sensor, an electron generated by a photon results in a pixel signal, but electrons generated by other factors act as noise to the pixel signal and distort the picture quality of an image generated by the image sensor. For example, a signal with noise is output at relatively low illumination or a dark image and the cause of the noise is a dark current induced by electrons generated at a photodiode region or a well region (including an oxide layer formed there within) for isolation. An image sensor with suppressed dark currents occurring at a photodiode or a well provides a clearer image.

### SUMMARY

At least some example embodiments of inventive concepts provide image sensors capable of generating a pixel signal providing a clearer image by suppressing dark currents.

According to at least one example embodiment of inventive concepts, an image sensor includes: a plurality of photodiodes, a plurality of wells and a plurality of metal layers. The plurality of wells isolate the plurality of photodiodes from each other. The plurality of metal layers are formed below the photodiodes, respectively. The plurality of metal layers are configured to receive a bias voltage.

At least one example embodiment of an inventive concept provides a method of manufacturing an image sensor including a plurality of metal layers, which are respectively formed below a plurality photodiodes, and configured to receive a bias voltage. According to at least this example embodiment, first etching is performed on a first region where the plurality of metal layers and a plurality of metal lines are formed, and second etching is performed on a second region where the plurality of metal layers are formed. The plurality of metal layers and the plurality of metal lines are formed in the first and second regions where the first etching and the second etching have been performed.

At least one other example embodiment of an inventive concept provides a method of manufacturing an image sensor including a plurality of metal layers, which are respectively formed below a plurality photodiodes and configured to receive a bias voltage. According to at least this example embodiment, the plurality of metal layers are formed to correspond to the plurality of photodiodes. A plurality of contacts for supplying electric power to the plurality of metal layers are formed, and a plurality of interconnecting metal lines are also formed.

At least one other example embodiment of an inventive concept provides an image sensor including a plurality of photodiodes, a plurality of wells and a plurality of conductive lines. The plurality of wells isolate the plurality of photodiodes from each other. Each of the plurality of conductive lines is formed above a corresponding one of the plurality of photodiodes and a well adjacent to the photodiode. The plurality of conductive lines are configured to receive a bias voltage.

At least one other example embodiment provides an electronic system. The electronics system includes: an image sensor, a memory and a processor. The image sensor is configured to generate an image. The memory is configured to store the generated image. The processor is coupled to the memory and the image sensor via a bus and configured to control operations of the image sensor and the memory. According to at least this example embodiment, the image sensor includes: a plurality of photodiodes, a plurality of wells and a plurality of metal layers. The plurality of wells isolate the plurality of photodiodes from each other. The plurality of metal layers are formed below the photodiodes, respectively. The plurality of metal layers are configured to receive a bias voltage.

At least one other example embodiment provides an electronic system. The electronics system includes: an image sensor, a memory and a processor. The image sensor is configured to generate an image. The memory is configured to store the generated image. The processor is coupled to the memory and the image sensor via a bus and configured to control operations of the image sensor and the memory. According to at least this example embodiment, the image sensor includes: a plurality of photodiodes, a plurality of wells and a plurality of conductive lines. The plurality of wells isolate the plurality of photodiodes from each other. Each of the plurality of conductive lines is formed above a corresponding one of the plurality of photodiodes and a well adjacent to the photodiode. The plurality of conductive lines are configured to receive a bias voltage.

According to at least some example embodiments, each of the plurality of metal layers has an area covering or overlapping a region of a corresponding one of the photodiodes and a portion of a well adjacent to the corresponding photodiode. An oxide layer may be formed below each of the plurality of wells. Each of the plurality of metal layers may have an area covering or overlapping the region of the corresponding one of the photodiodes and covering or overlapping a portion of the oxide layer adjacent to the corresponding photodiode. The bias voltage may be the same or substantially the same as a voltage applied to a gate of one transistor among a plurality of transistors configured to control an operation of each of the photodiodes.

### BRIEF DESCRIPTION OF THE DRAWINGS

Inventive concepts will become more apparent by describing in detail example embodiments thereof with reference to the attached drawings in which:

FIG. 1 is a sectional view of a pixel array included in an image sensor according to an example embodiment;

FIG. 2 is a layout of a unit pixel included in the pixel array illustrated in FIG. 1;

FIG. 3 is a sectional view of a part of the unit pixel illustrated in FIG. 2;

FIGS. 4A through 4C are sectional views of stages in a method of manufacturing an image sensor according to an example embodiment;

FIG. 5 is a flowchart of the method illustrated in FIGS. 4A through 4C;

FIGS. 6A through 6C are sectional views of stages in a method of manufacturing an image sensor according to another example embodiment;

FIG. 7 is a flowchart of the method illustrated in FIGS. 6A through 6C;

FIG. 8 is a layout of a unit pixel included in a pixel array of an image sensor according to another example embodiment;

FIG. 9 is a sectional view of the unit pixel illustrated in FIG. 8;

FIG. 10 is a circuit diagram of a unit pixel included in an image sensor according to an example embodiment;

FIG. 11 is a block diagram of an image sensor according to another example embodiment; and

FIG. 12 is a block diagram of an electronic system including an image sensor according to an example embodiment.

### DETAILED DESCRIPTION

Inventive concepts will now be described more fully hereinafter with reference to the accompanying drawings, in which example embodiments are shown. Inventive concepts may, however, be embodied in many different forms and should not be construed as limited to the example embodiments set forth herein. Rather, these example embodiments are provided so that this disclosure will be thorough and complete, and will fully convey the scope to those skilled in the art. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. In addition, when an element is referred to as “transmitting” data or a signal to another element, it can directly transmit the data or the signal to the other element or at least one intervening element may be present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first signal could be termed a second signal, and, similarly, a second signal could be termed a first signal without departing from the teachings of the disclosure.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

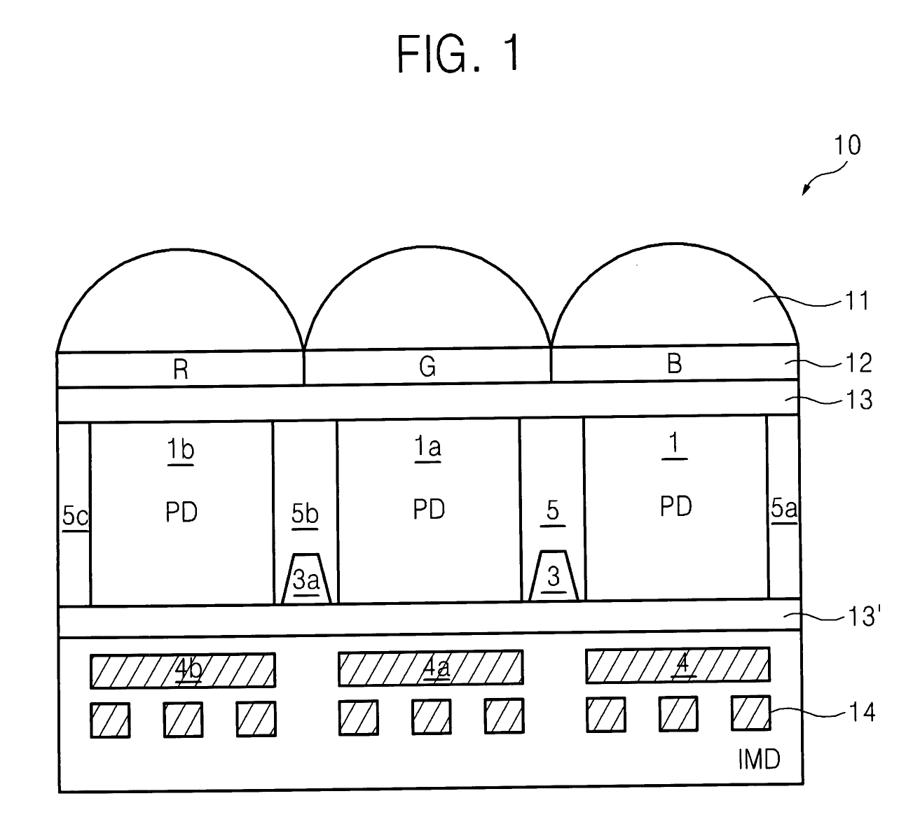

FIG. 1 is a sectional view of a pixel array 10 included in an image sensor according to an example embodiment. In this example, the image sensor is a back-side illumination (BSI) image sensor including light reflective metal layers 4, 4a, and 4b and interconnecting metal lines 14 below photodiodes (PDs) 1, 1a, and 1b.

Referring to FIG. 1, the pixel array 10 includes a plurality of the PDs 1, 1a, and 1b separated by a plurality of wells 5, 5a, 5b, and 5c. Oxide layers 3 and 3a are formed at lower portions of the wells 5 and 5a, respectively. A first P-type layer 13 is formed on an upper surface of the PDs 1, 1a and 1b and the wells 5, 5a, 5b, and 5c. A plurality of color filters 12 are formed on the first P-type layer 13. A plurality of lenses 11 are formed on the plurality color filters 12, respectively. A second P-type layer 13′ is formed on a lower surface of the PDs 1, 1a, and 1b, the plurality of wells 5, 5a, 5b, and 5c, and the plurality of oxide layers 3 and 3a. A plurality of the metal layers 4, 4a, and 4b and a plurality of the metal lines 14 are formed under the second P-type layer 13′.

In example operation, the lenses 11 collect light incident on the respective PDs 1, 1a, and 1b, and the color filters 12 filter the incident light passing through the lenses 11 to pass red (R), green (G), and blue (B) spectrums, respectively.

The first P-type layer 13 suppresses a dark current induced by electrons generated at the top of the PDs 1, 1a, and 1b. As noted above, the PDs 1, 1a, and 1b are formed between the first P-type layer 13 and the second P-type layer 13′. The slopes of potential barriers among the first P-type layer 13, the PDs 1, 1a, and 1b, and the second P-type layer 13′ (e.g., the slope of potential barrier between the PDs 1, 1a, and 1b and the second P-type layer 13′) may be controlled by the concentration of the second P-type layer 13′. For example, when the concentration of the second P-type layer 13′ increases, the slope of the potential barrier between the PDs 1, 1a, and 1b and the second P-type layer 13′ also increases.

The PDs 1, 1a, and 1b generate photoelectrons in response to incident light that passes through the lenses 11, respectively. The wells 5, 5a, 5b, and 5c isolate the PDs 1, 1a, and 1b from one another. Generally, the PDs 1, 1a, and 1b are implemented using an N-type semiconductor, whereas the wells 5, 5a, 5b, and 5c are implemented using a P-type semiconductor. The wells 5, 5a, 5b, and 5c have a higher potential barrier than the PDs 1, 1a, and 1b, and thus, the wells 5, 5a, 5b, and 5c suppress and/or prevent electrons generated at each of the PDs 1, 1a, and 1b from overflowing into an adjacent PD 1, 1a, or 1b.

The oxide layer 3 or 3a disposed at the bottom of each well 5, 5a, 5b, or 5c may be formed using, for example, a shallow trench insulation (STI) process. The STI process is known, and thus, a detailed description thereof will be omitted.

The plurality of the metal lines 14 and the plurality of the metal layers 4, 4a, and 4c are formed in an inter-metal dielectric (IMD) region. The plurality of metal lines 14 form an electrical interconnection necessary for the operation of the pixel array 10. The plurality of the metal layers 4, 4a, and 4c reflect incident light passing through the PDs 1, 1a, and 1b back toward the PDs 1, 1a, and 1b.

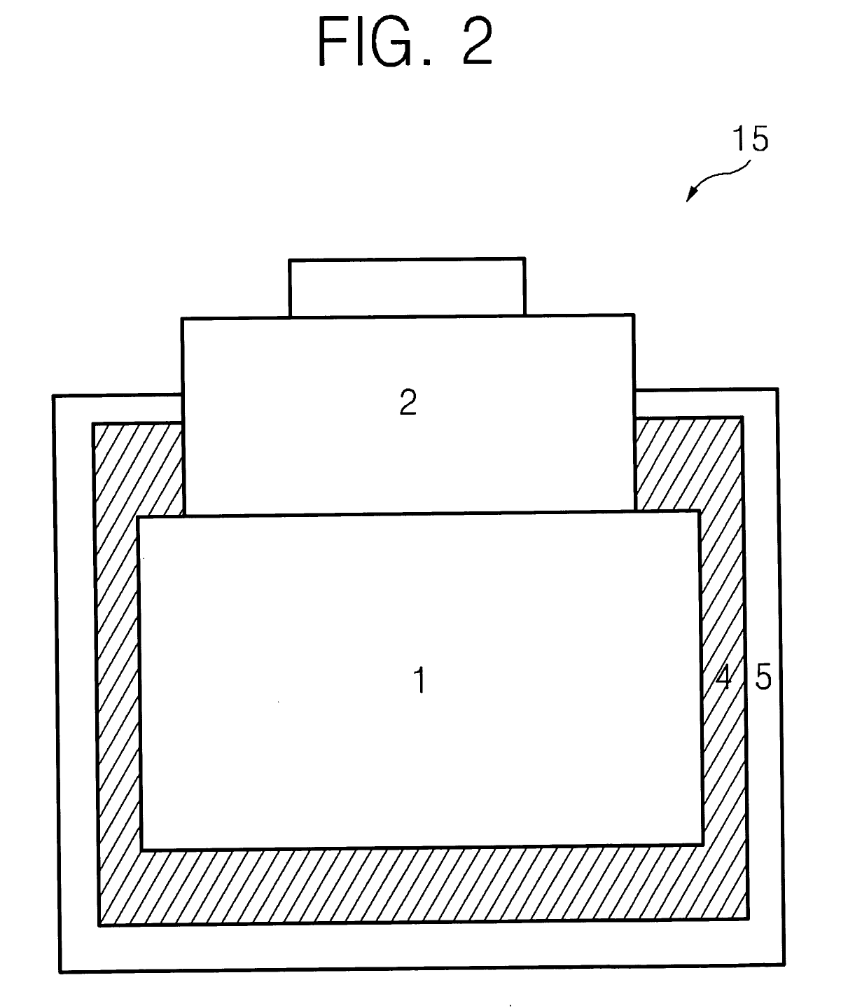

Although not shown in FIG. 1, a negative bias voltage is applied to the metal layers 4, 4a, and 4c. As a result of the negative bias voltage, a dark current is suppressed at the PDs 1, 1a, and 1b and the wells 5, 5a, 5b, and 5c. This procedure will be described in more detail below with reference to FIGS. 2 through 7.

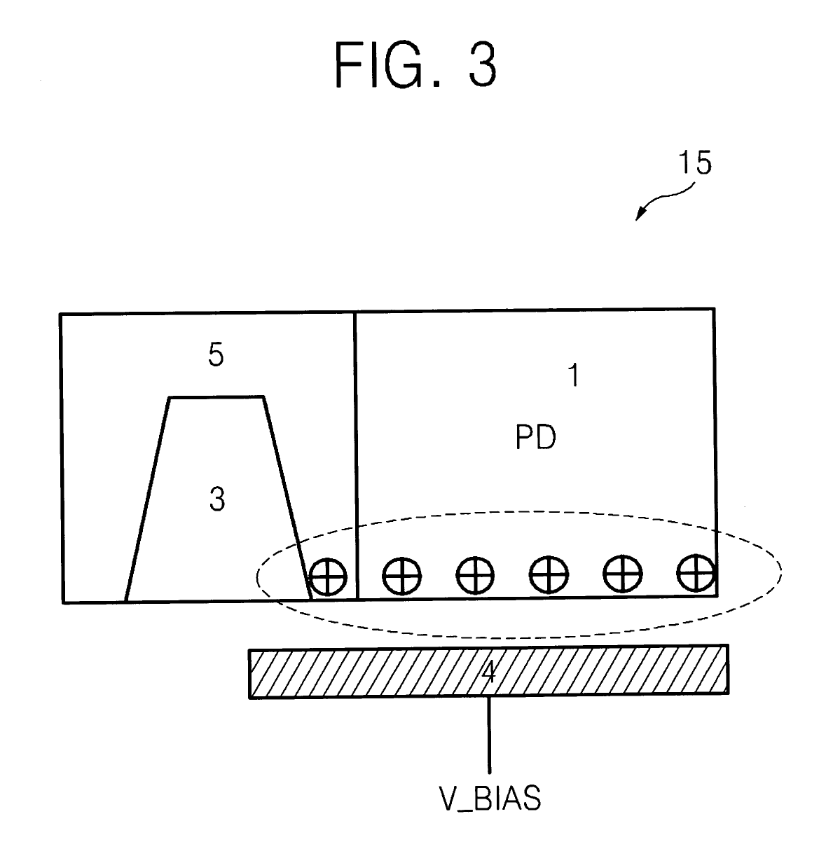

FIG. 2 is a layout of a unit pixel 15 included in the pixel array 10 illustrated in FIG. 1. FIG. 3 is a sectional view of part of the unit pixel 15 illustrated in FIG. 2. FIG. 2 illustrates the unit pixel 15 viewed from above, and thus, schematically only shows the PD 1, a gate 2 of a transfer transistor (not shown), the well 5, and the metal layer 4.

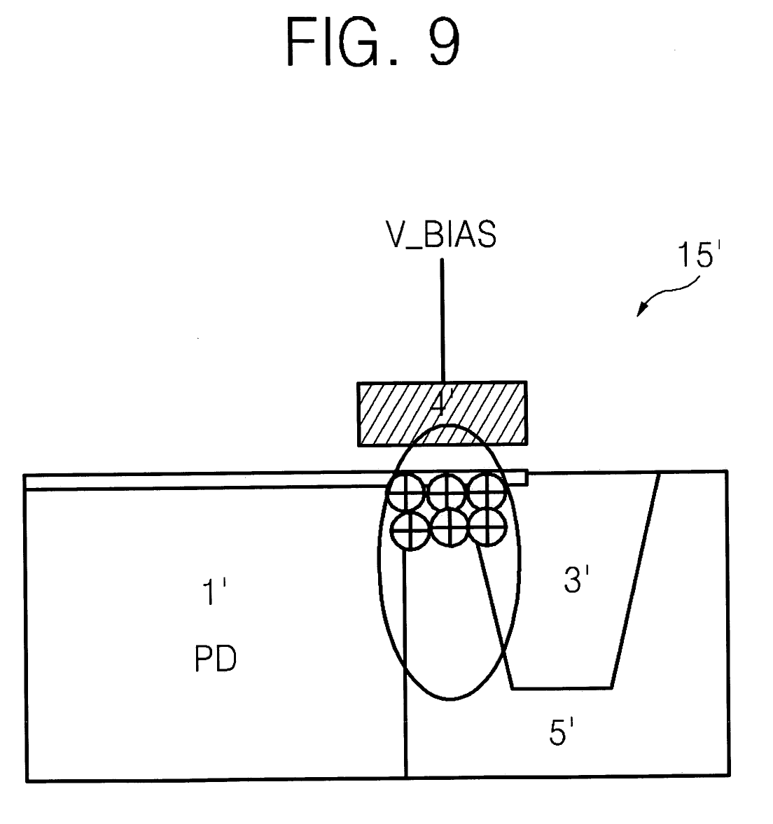

Referring to FIGS. 2 and 3, the transfer transistor outputs electrons accumulated at the PD 1 to a floating diffusion (not shown) in response to a transfer signal applied to the gate 2. The operation of the unit pixel 15 included in the pixel array 10 will be described in more detail later with reference to FIG. 9.

The metal layer 4 is formed below the PD 1 and configured to receive a bias voltage V_BIAS. The metal layer 4 has an area covering (overlapping) the whole region of the PD 1 and a portion or part of the well 5.

Referring back to FIG. 1, the area of the metal layer 4 on the right covers (overlaps) the whole region of the PD 1 and portions of the adjacent wells 5 and 5a. The area of the metal layer 4a at the middle covers (overlaps) the whole region of the PD 1a and portions of the adjacent wells 5 and 5b. The area of the metal layer 4b on the left covers (overlaps) the whole region of the PD 1b and portions of the adjacent wells 5b and 5c.

When the oxide layer 3 is formed within the well 5 as illustrated in FIG. 3, the metal layer 4 may have an area covering (overlapping) the whole region of the PD 1, a portion of the well 5, and a portion of the oxide layer 3.

The bias voltage V_BIAS applied to the metal layer 4 may be a ground voltage or a negative voltage lower than the ground voltage. As shown in FIG. 3, for example, when the negative bias voltage V_BIAS is applied to the metal layer 4, holes are accumulated at the lower portion of the PD 1 and a part of the lower portion of the well 5.

The holes accumulated at the well 5 and the PD 1 become extinct dissipate when they combine with electrons, which are generated at the surface of the PD 1 due to damage occurring during a front process, and induces a dark current.

The dark current is suppressed by applying the bias voltage V_BIAS to the metal layer 4, which reduces noise in a pixel signal. As a result, image sensors according to example embodiments provide a clearer image.

The performance of the metal layer 4 suppressing the dark current increases when the area of the metal layer 4 increases and the distance between the PD 1 and the metal layer 4 and the bias voltage V_BIAS decrease. When designing a pixel array 10, the values of those factors affecting the performance may be determined considering the operation characteristics and/or environment of the pixel array 10.

The bias voltage V_BIAS applied to the metal layer 4 may be provided independently. Alternatively, the bias voltage V_BIAS may be the same or substantially the same as a voltage applied to one of a plurality of transistors (not shown) (e.g., a transfer transistor and a select transistor) controlling the operation of the PD 1. At this time, a special metal line for providing the bias voltage V_BIAS may be reduced or is not necessary, thereby facilitating the designing and/or manufacturing of image sensors according to example embodiments.

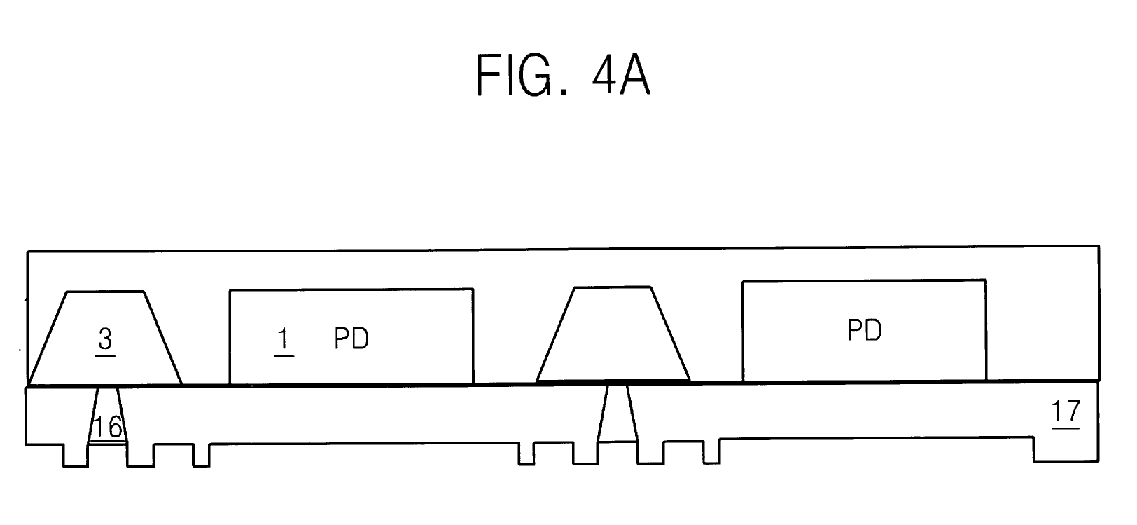

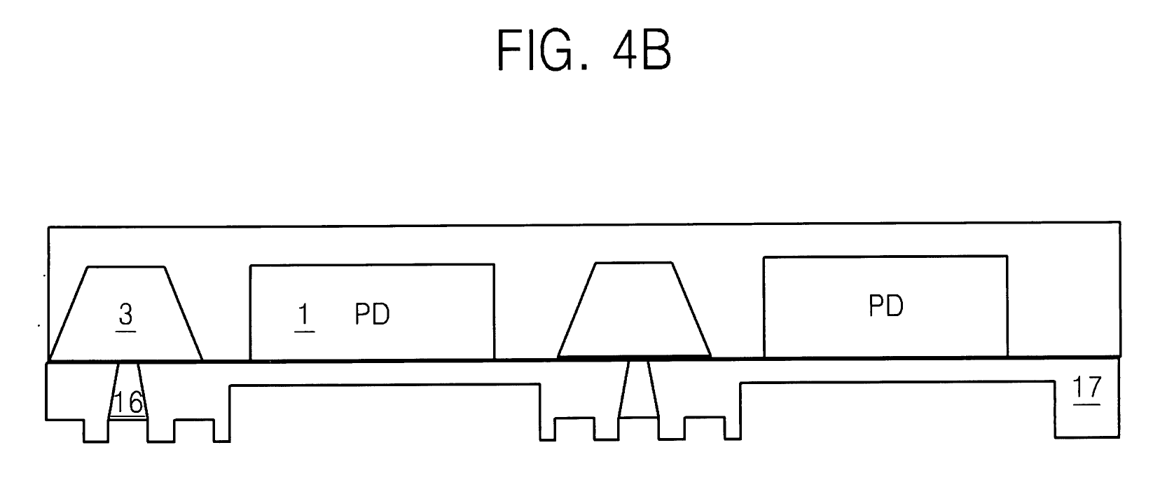

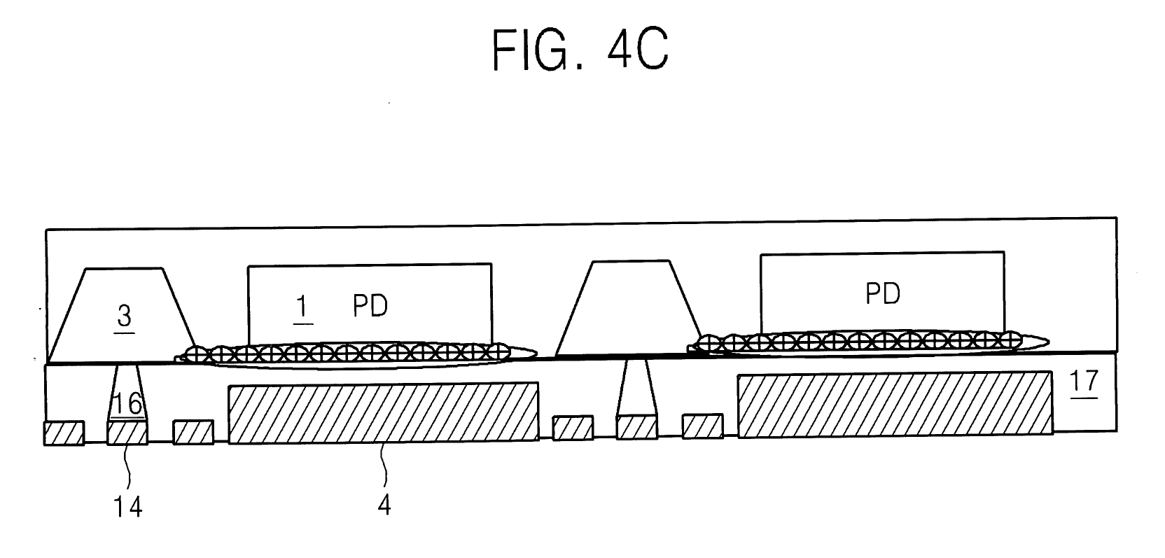

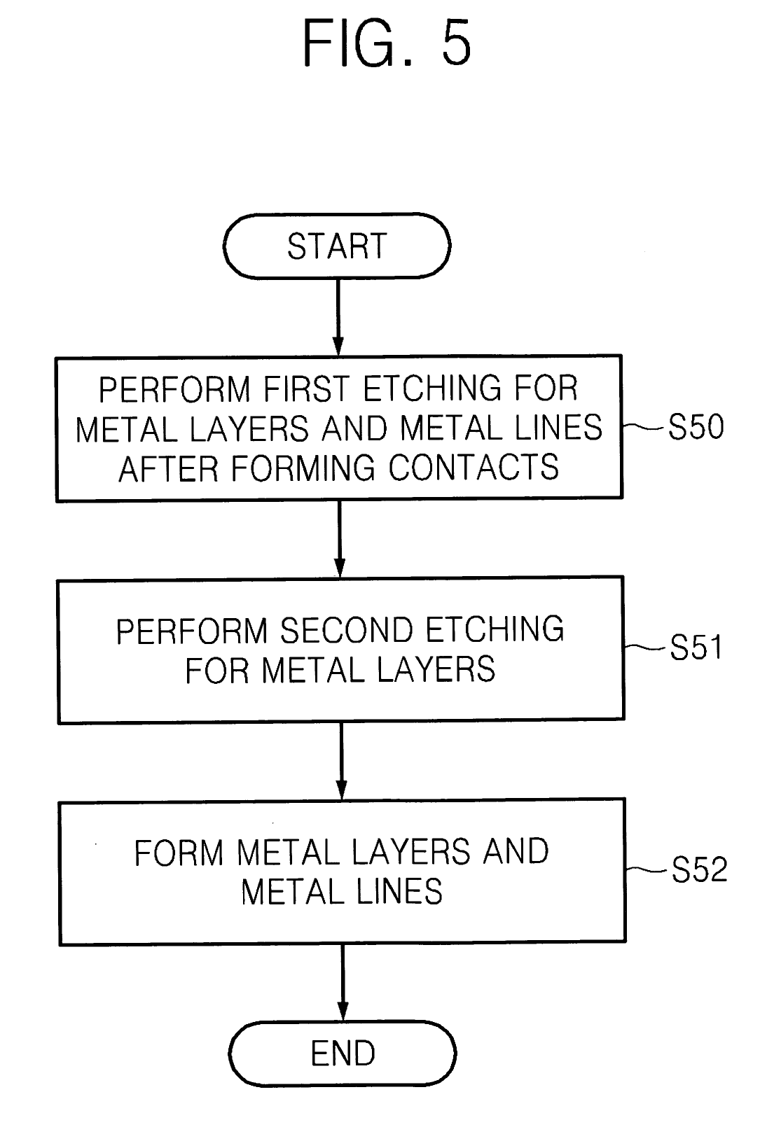

FIGS. 4A through 4C are sectional views of stages in a method of manufacturing an image sensor according to an example embodiment. FIG. 5 is a flowchart describing the method illustrated in FIGS. 4A through 4C.

Hereinafter, a procedure of forming metal layers 4 for suppressing a dark current, which is carried out after forming PDs 1, oxide layers 3, contacts 16 for supplying electric power, and an IMD region 17, will be described.

Referring to FIGS. 4A through 4C and 5, after forming the contacts 16, at S50 first etching is performed on a region where the metal layers 4 for reflection and the metal lines 14 for interconnection will be formed. Referring specifically to FIG. 4A, in the first etching an etch depth for the reflective metal layers 4 is the same or substantially the same as that for the interconnecting metal lines 14.

Thereafter, at S51 second etching is performed on a region where the reflective metal layers 4 will be formed. Referring specifically to FIG. 4B, the etch depth for the reflective metal layers 4 is greater than that for the interconnecting metal lines 14. This is because the performance of the metal layers 4 suppressing a dark current increases when they are close to the PDs 1.

At S52, the metal layers 4 and the metal lines 14 are formed in the region where the first and second etching has been performed. Referring to FIG. 4C, for example, if a negative bias voltage is applied to the metal layer 4, holes are accumulated in lower portions and adjacent regions of the PDs 1 above the metal layers 4. The holes accumulated in the lower portions and adjacent regions of the PDs 1 combine with electrons to suppress a dark current.

The above-described procedure (S50 through S52 in FIG. 5) may be performed using a copper (Cu) dual-damascene process, but example embodiments are not restricted thereto. The dual damascene process is known, and thus, a detailed description thereof will be omitted.

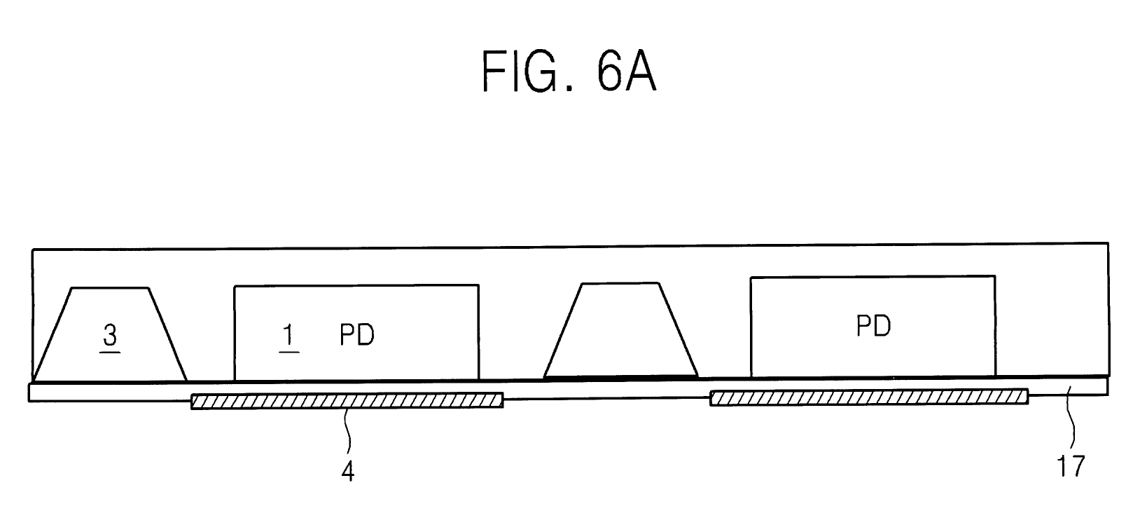

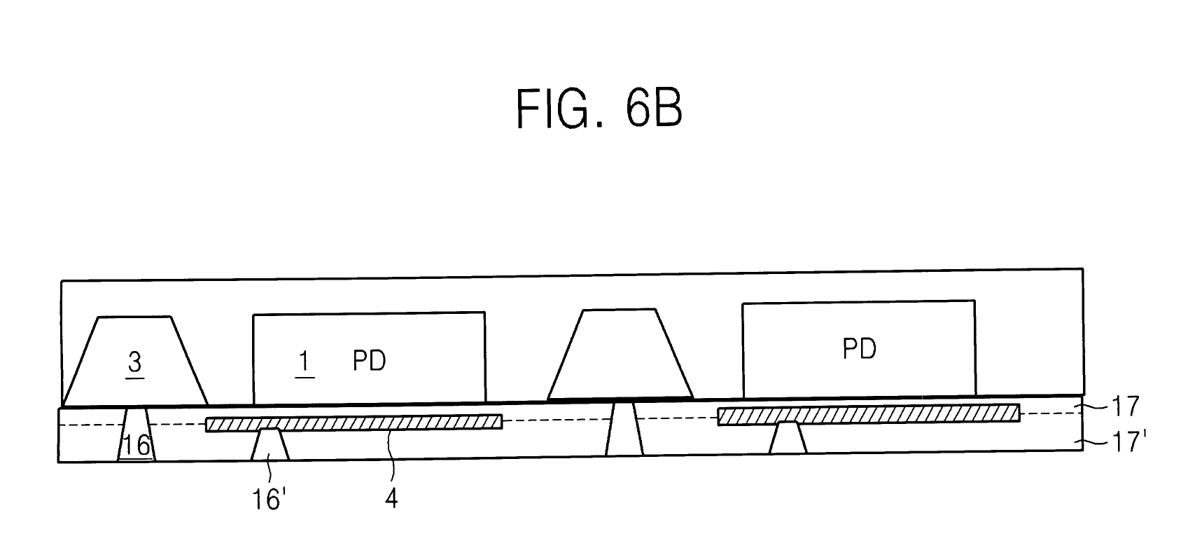

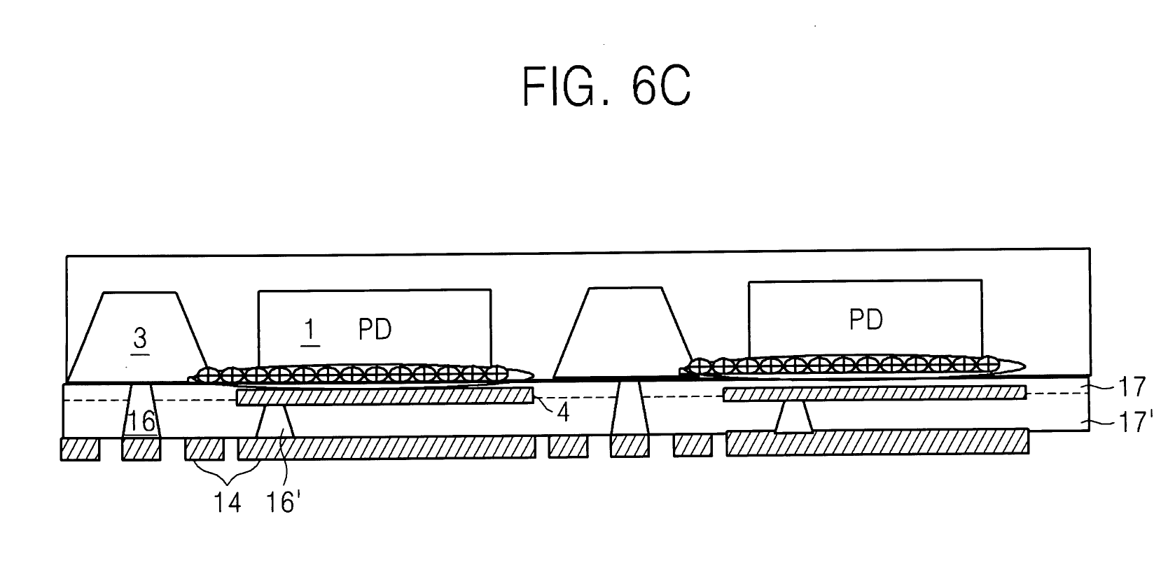

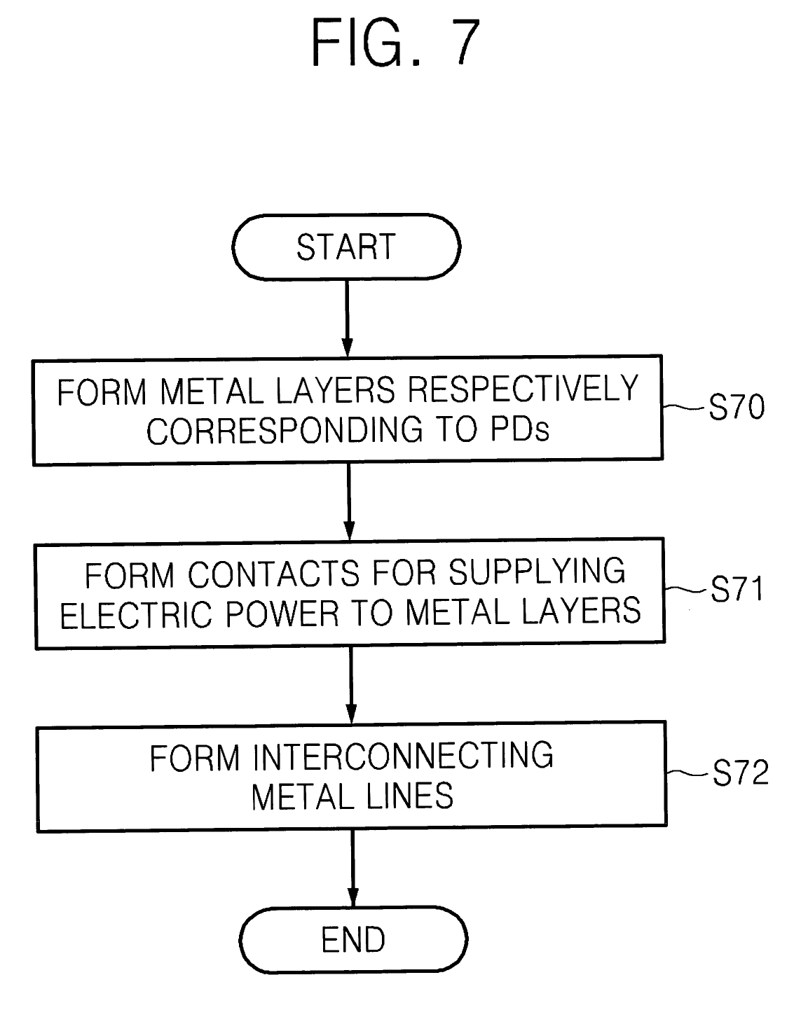

FIGS. 6A through 6C are sectional views of stages in a method of manufacturing an image sensor according to another example embodiment. FIG. 7 is a flowchart of the method illustrated in FIGS. 6A through 6C.

Hereinafter, a procedure of forming the metal layers 4 for suppressing a dark current, which is carried out after forming the PDs 1, the oxide layers 3, and a partial IMD region 17, will be described.

Referring to FIGS. 6A and 7, at S70 the metal layers 4, respectively corresponding to the PDs 1, are formed after forming the partial IMD region 17. Thereafter, referring to FIGS. 6B and 7, a remaining IMD region 17′ is formed below the metal layers 4, and a plurality of contacts 16 and 16′ including the contacts 16′ for supplying electric power (e.g., a bias voltage) to the metal layers 4 are formed at S71.

Referring to FIGS. 6C and 7, after forming the contacts 16 and 16′, the interconnecting metal lines 14 are formed at S72. In FIG. 6C, the metal layers 4 are closer to the PDs 1 than the interconnecting metal lines 14. The metal layers 4 are formed closer to the PDs 1 to increase the performance of the metal layers 4 suppressing a dark current.

Still referring to FIG. 6C, if a negative bias voltage is applied to the metal layer 4, holes accumulate in lower portions and adjacent regions of the PDs 1 above the metal layers 4. The holes accumulated in the lower portions and adjacent regions of the PDs 1 combine with electrons to suppress a dark current.

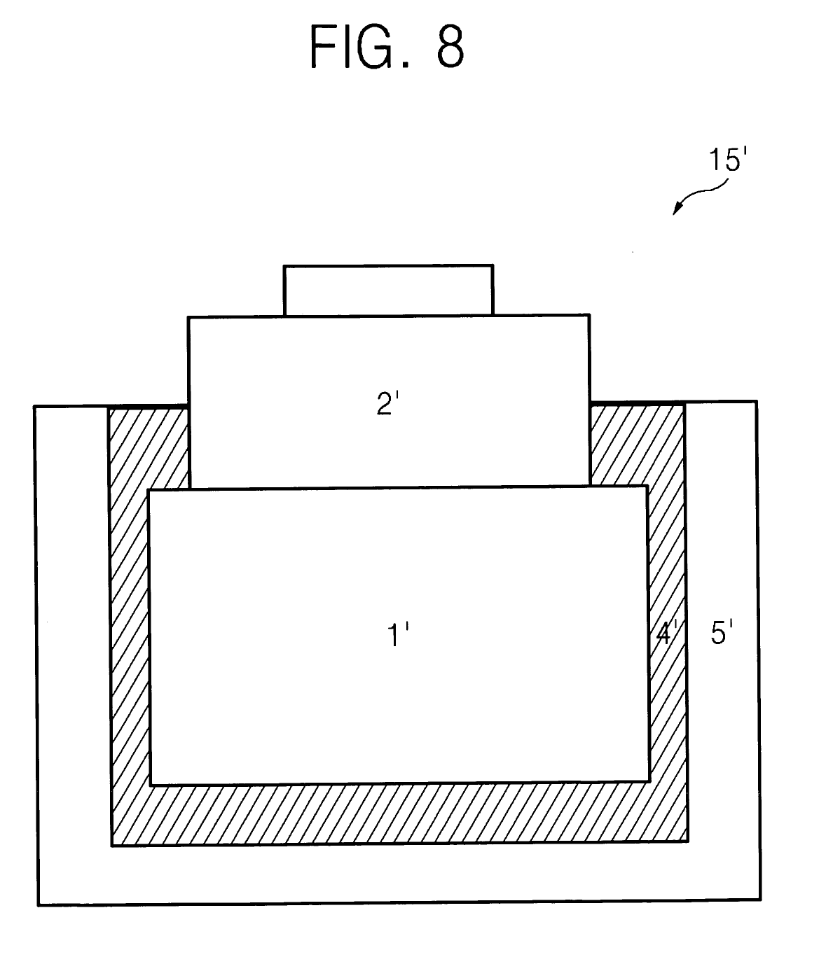

FIG. 8 is a layout of a unit pixel 15′ included in a pixel array of an image sensor according to another example embodiment. FIG. 9 is a sectional view of the unit pixel 15′ illustrated in FIG. 8. FIG. 8 illustrates the unit pixel 15′ viewed from above, and thus, only a PD 1′, a gate 2′ of a transfer transistor (not shown), a well 5′, and a conductive line 4′ are shown.

Referring to FIGS. 8 and 9, the image sensor includes a plurality of PDs 1′, a plurality of wells 5′ isolating the PDs 1′ from each other, and a plurality of conductive lines 4′.

The conductive line 4′ is formed above the PD 1′ and the well 5′ adjacent to the PD 1′ and is configured to receive a bias voltage V_BIAS. The conductive line 4′ guides light to the PD 1′ and also suppresses a dark current in response to the bias voltage V_BIAS applied thereto. The conductive line 4′ may be a metal line or a gate poly line, but example embodiments are not restricted thereto.

The conductive line 4′ may have an area covering (overlapping) the whole region of the PD 1′ and a portion of the well 5′ adjacent to the PD P. When an oxide layer 3′ is formed within the well 5′ as illustrated in FIG. 9, the conductive line 4′ may have an area covering (overlapping) a portion of the PD 1′, a portion of the well 5′, and a portion of the oxide layer 3′.

The bias voltage V_BIAS applied to the conductive line 4′ may be a ground voltage or a negative voltage lower than the ground voltage. When the negative bias voltage V_BIAS is applied to the conductive line 4′, holes are accumulated at a part of an upper portion of the well 5′ and a part of an upper portion of the PD 1′.

The holes accumulated at the well 5′ and the PD 1′ dissipate (e.g., become extinct) when they combine with electrons, which cause a dark current. In this example, the dark current is suppressed by the bias voltage V_BIAS applied to the conductive line 4′, thereby reducing noise in a pixel signal. As a result, image sensors according to example embodiments may provide a clearer image.

The performance of the conductive line 4′ suppressing the dark current increases when the area of the conductive line 4′ increases and the distance between the PD 1′ and the conductive line 4′ and the bias voltage V_BIAS decrease. When the pixel array is designed, the values of those factors affecting the performance may be determined considering the operation characteristics and/or environment of the pixel array.

As described with reference to FIGS. 2 and 3 above, the bias voltage V_BIAS applied to the conductive line 4′ may be provided independently or may be the same or substantially the same as a voltage applied to one of a plurality of transistors (not shown) (e.g., a transfer transistor and/or a select transistor) controlling the operation of the PD 1′.

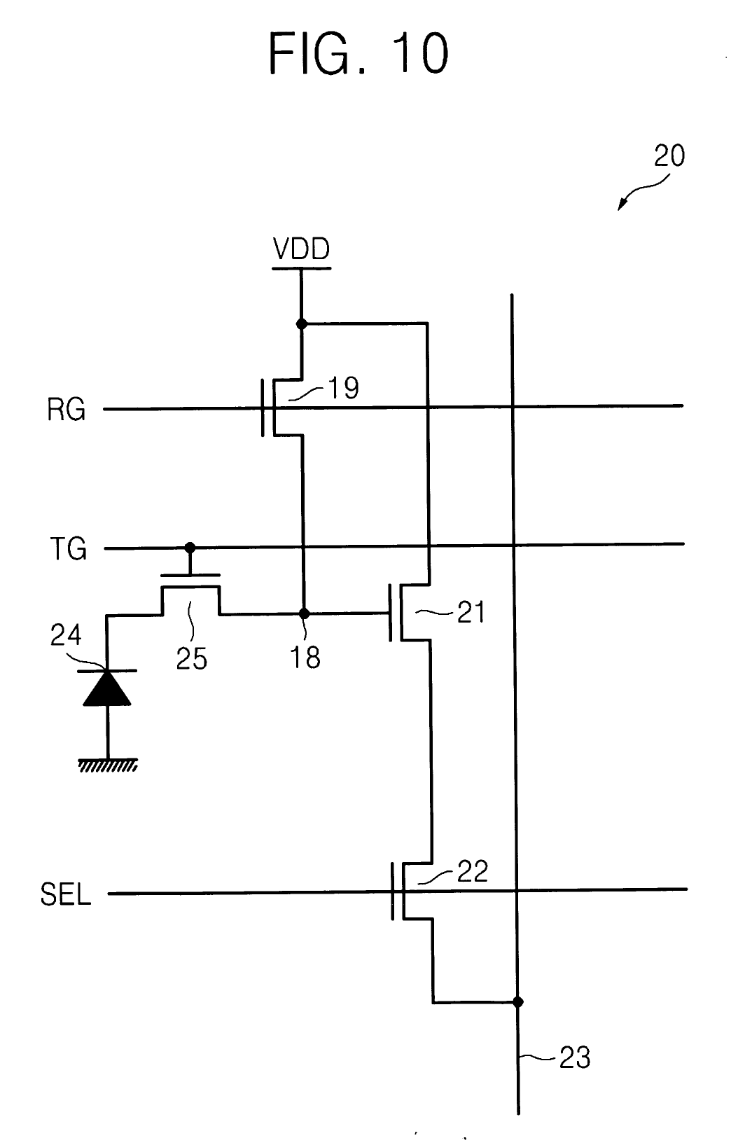

FIG. 10 is a circuit diagram of a unit pixel 20 included in an image sensor according to another example embodiment. In FIG. 10, the pixel 20 is a four-transistor (4T) pixel.

Referring to FIG. 10, the pixel 20 includes a PD 24, a floating diffusion region 18, and a plurality of transistors 19, 21, 22, and 25.

The PD 24 generates photoelectrons in response to incident light. The transfer transistor 25 selectively transmits the photoelectrons from the PD 24 to the floating diffusion region 18 in response to a transfer signal TG. The reset transistor 19 resets the floating diffusion region 18 to a given, desired or predetermined voltage VDD in response to a reset signal RG.

The drive transistor 21 outputs a voltage that varies in response to a voltage level of the floating diffusion region 18 through a vertical signal line 23. The select transistor 22 selects a pixel to output a pixel signal in response to a selection signal SEL.

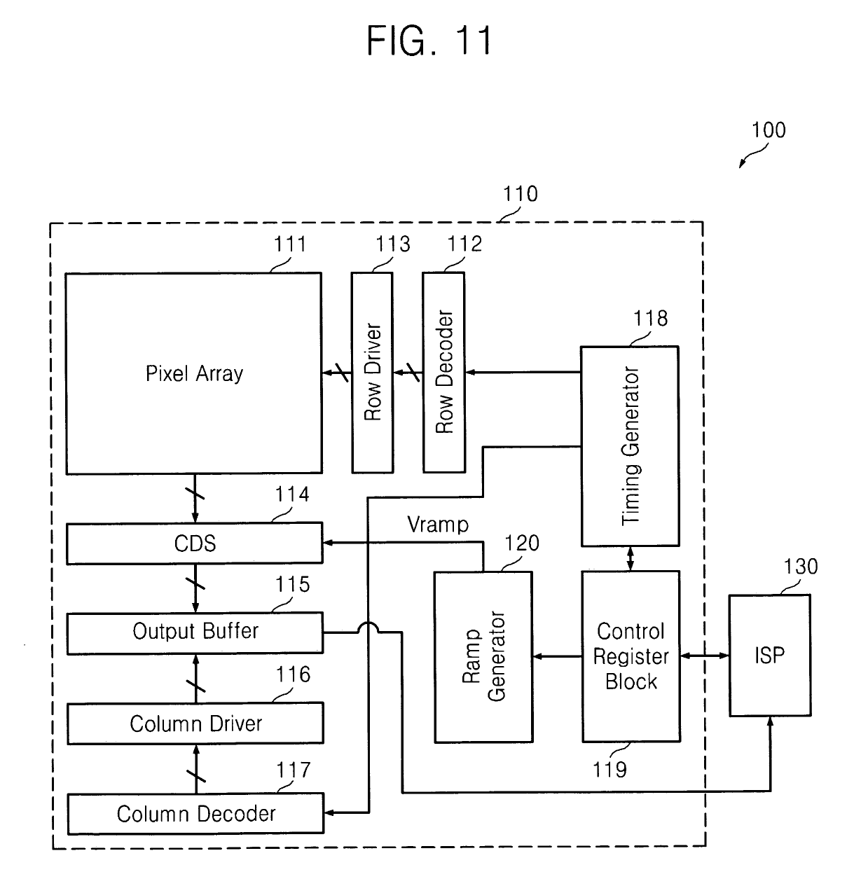

FIG. 11 is a block diagram of an image sensor 100 according to another example embodiment.

Referring to FIG. 11, the image sensor 100 includes a photoelectric converter 110 and an image signal processor (ISP) 130. Each of the photoelectric converter 110 and the image signal processor 130 may be implemented in a separate chip or module.

The photoelectric converter 110 generates an image signal corresponding to a photographed subject based on incident light. The photoelectric converter 110 includes a pixel array 111, a row decoder 112, a row driver 113, a correlated double sampling (CDS) block 114, an output buffer 115, a column driver 116, a column decoder 117, a timing generator 118, a control register block 119, and a ramp generator 120.

The pixel array 111 includes a plurality of pixels arranged in a two-dimensional matrix. The plurality of pixels are connected to a plurality of row lines (not shown), respectively. The plurality of pixels are also connected to a plurality of column lines (not shown), respectively. Each of the pixels includes a red pixel, a green pixel and a blue pixel. The red pixel converts red spectrum light into an electrical signal. The green pixel converts green spectrum light into an electrical signal. The blue pixel converts blue spectrum light into an electrical signal. In addition, as illustrated in FIG. 1, a color filter is provided above each of the pixels included in the pixel array 111. Each color filter transmits a particular color spectrum of light.

The row decoder 112 decodes a row control signal (e.g., an address signal) generated by the timing generator 118. The row driver 113 selects at least one row line from among the plurality of row lines in the pixel array 111 in response to a decoded row control signal from the row decoder 112.

The CDS block 114 performs CDS on a pixel signal output from a pixel connected to a column line among the plurality of column lines in the pixel array 111. In more detail, for example, the CDS block 114 performs CDS on a pixel signal output from a pixel connected to one of the column lines in the pixel array 111, generates a sampling signal (not shown), compares the sampling signal with a ramp signal Vramp, and generates a digital signal according to a result of the comparison.

The output buffer 115 buffers and outputs signals output from the CDS block 114 in response to a column control signal (e.g., an address signal) output from the column driver 116.

The column driver 116 selectively activates at least one column line among the plurality of column lines in the pixel array 111 in response to a decoded control signal (e.g., an address signal) from the column decoder 117. The column decoder 117 decodes a column control signal (e.g., an address signal) generated by the timing generator 118.

The timing generator 118 generates at least one control signal for controlling the operation of at least one among the pixel array 111, the row decoder 112, the output buffer 115, the column decoder 117, and the ramp generator 120 based on a command output from the control register block 119.

The control register block 119 generates various commands for controlling the elements of the photoelectric converter 110. The ramp generator 120 outputs the ramp signal Vramp to the CDS block 114 in response to a command generated by the control register block 119. The ISP 130 generates an image corresponding to a photographed subject based on pixel signals output from the photoelectric converter 110.

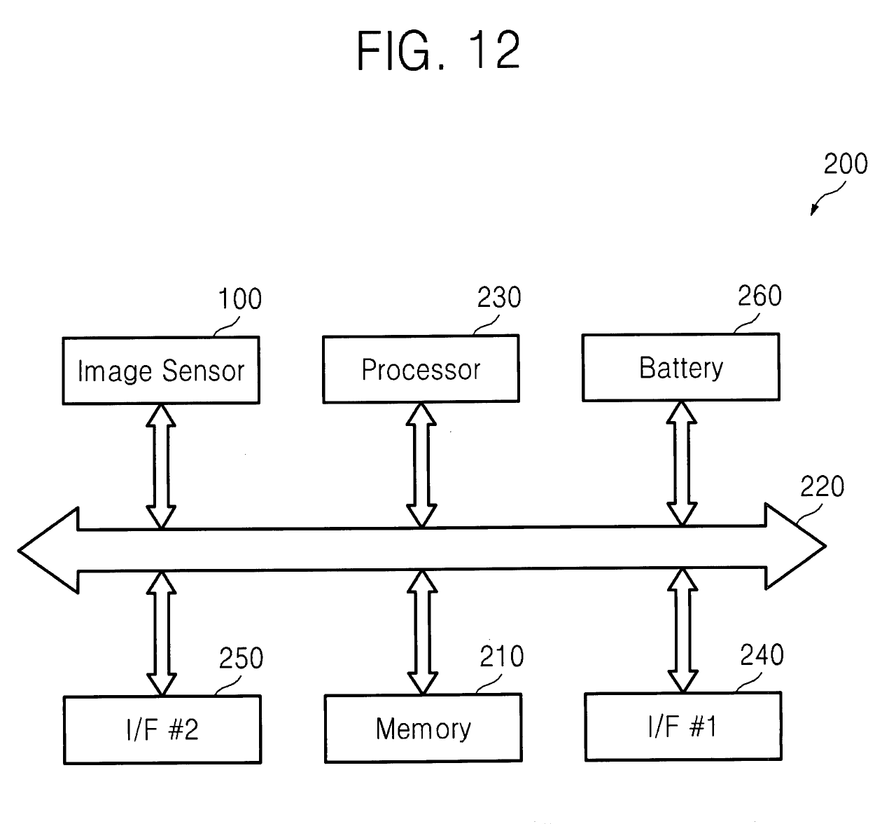

FIG. 12 is a block diagram of an electronic system 200 including the image sensor 100 according to an example embodiment.

Referring to FIG. 12, the electronic system 200 includes the image sensor 100, a memory 210, and a processor 230. Each of the image sensor 100, the memory 210 and the processor 2300 are connected to a system bus 220. The electronic system 200 may be a digital camera, a mobile phone equipped with a digital camera, a satellite system equipped with a camera, or the like. However, example embodiments are not restricted thereto.

The processor 230 generates control signals for controlling the operations of the image sensor 100 and the memory 210. The image sensor 100 generates an image corresponding to a photographed subject and the memory 210 stores the image.

When the electronic system 200 is embodied as a portable application, the electronic system 200 may further include a battery 260. The battery 260 supplies operating power to the image sensor 100, the memory 210, and the processor 230.

The electronic system 200 may also include a first interface 240 (e.g., an input/output unit) to communicate data with an external data processing device. When the electronic system 200 is a wireless system, the electronic system 200 may further include a second interface (e.g., a wireless interface) 250. The wireless system may be a wireless device such as a personal digital assistant (PDA), a portable computer, a wireless telephone, a pager, a digital camera, a radio frequency identification (RFID) reader, an RFID system, etc. The wireless system may also be a wireless local area network (WLAN) system or a wireless personal area network (WPAN) system. Moreover, the wireless system may be a cellular network.

While inventive concepts have been particularly shown and described with reference to example embodiments thereof, it will be understood by those of ordinary skill in the art that various changes in forms and details may be made therein without departing from the spirit and scope of the inventive concepts as defined by the following claims.

What is claimed is:

1. An image sensor comprising:
a plurality of photodiodes;
a plurality of wells isolating the plurality of photodiodes from each other; and
a plurality of metal layers configured to receive a bias voltage, each of the plurality of metal layers being formed below a corresponding one of the plurality of photodiodes.

2. The image sensor of claim 1, wherein each of the plurality of metal layers has an area overlapping a region of a corresponding one of the photodiodes and overlapping a portion of a well adjacent to the corresponding photodiode.

3. The image sensor of claim 2, further comprising:
an oxide layer formed below each of the plurality of wells; wherein
each of the plurality of metal layers has an area overlapping the region of the corresponding one of the photodiodes and overlapping a portion of the oxide layer adjacent to the corresponding photodiode.

4. The image sensor of claim 2, wherein the bias voltage is the same as a voltage applied to a gate of one transistor among a plurality of transistors configured to control an operation of each of the photodiodes.

5. A method of manufacturing an image sensor, the method comprising:
first etching a first region where a plurality of metal layers and a plurality of metal lines are formed;
second etching a second region where the plurality of metal layers are formed; and
forming the plurality of metal layers and the plurality of metal lines in the first and second regions; wherein
each of the plurality of metal layers is formed below a respective one of the plurality of photodiodes, and
the plurality of metal layers are configured to receive a bias voltage.

6. A method of manufacturing an image sensor, the method comprising:
forming a plurality of metal layers, each of the plurality of metal layers being formed to correspond to one of a plurality of photodiodes;
forming a plurality of contacts for supplying electric power to the plurality of metal layers; and
forming a plurality of interconnecting metal lines; wherein
each of the plurality of metal layers are formed below a corresponding one of the plurality of photodiodes, and
the plurality of metal layers are configured to receive a bias voltage.

7. An image sensor comprising:
a plurality of photodiodes;
a plurality of wells isolating the plurality of photodiodes from each other; and
a plurality of conductive lines, each of the plurality of conductive lines being formed above a corresponding one of the plurality of photodiodes and a well adjacent to the photodiode, the plurality of conductive lines being configured to receive a bias voltage.

8. The image sensor of claim 7, further comprising:
an oxide layer formed above each of the plurality of wells; wherein
each of the plurality of conductive lines has an area overlapping a portion of a corresponding one of the plurality of photodiodes and overlapping a portion of the oxide layer adjacent to the corresponding photodiode.

9. The image sensor of claim 8, wherein the bias voltage is the same as a voltage applied to a gate of one of a plurality of transistors configured to control an operation of each of the plurality of photodiodes.

10. An electronic system comprising:
the image sensor of claim 1 configured to generate an image;
a memory configured to store the generated image; and
a processor coupled to the memory and the image sensor via a bus, the processor being configured to control operations of the image sensor and the memory.

11. The electronics system of claim 10, wherein each of the plurality of metal layers has an area overlapping a region of a corresponding one of the photodiodes and overlapping a portion of a well adjacent to the corresponding photodiode.

12. The electronics system of claim 11, further comprising:
an oxide layer formed below each of the plurality of wells; wherein
each of the plurality of metal layers has an area overlapping the region of the corresponding one of the photodiodes and overlapping a portion of the oxide layer adjacent to the corresponding photodiode.

13. The electronics system of claim 11, wherein the bias voltage is the same as a voltage applied to a gate of one transistor among a plurality of transistors configured to control an operation of each of the photodiodes.

14. An electronic system comprising:
the image sense of claim 7 configured to generate an image;
a memory configured to store the generated image; and
a processor coupled to the memory and the image sensor via a bus, the processor being configured to control operations of the image sensor and the memory.

15. The electronic system of claim 14, further comprising:
an oxide layer formed above each of the plurality of wells; wherein
each of the plurality of conductive lines has an area overlapping a portion of a corresponding one of the plurality of photodiodes and overlapping a portion of the oxide layer adjacent to the corresponding photodiode.

16. The electronic system of claim 15, wherein the bias voltage is the same as a voltage applied to a gate of one of a plurality of transistors configured to control an operation of each of the plurality of photodiodes.

17. The electronic system of claim 14, wherein each of the plurality of metal layers has an area overlapping a region of a corresponding one of the photodiodes and overlapping a portion of a well adjacent to the corresponding photodiode.
